(19) United States
(12) Patent Application Publication
(10) Pub. No.: US 2011/0233631 A1
(43) Pub. Date: Sep. 29, 2011

(54) VERTICALLY STACKED FUSION SEMICONDUCTOR DEVICE

(76) Inventors: Yong-hoon SON, Yongin-si (KR); Ki-hyun Hwang, Seongnam-gi (KR)

(21) Appl. No.: 13/069,650

(22) Filed: Mar. 23, 2011

(30) Foreign Application Priority Data
Mar. 23, 2010 (KR) 10-2010-0025872

(51) Int. Cl. H01L 27/105

(52) U.S. Cl. 257/298; 257/E27.081

(57) ABSTRACT

A vertically stacked fusion semiconductor device includes a channel portion which extends in a first direction with respect to a surface of a semiconductor layer, a common source line which extends in a second direction different from the first direction and is electrically connected to the channel portion, a first gate structure which is electrically connected to the common source line via the channel portion and a second gate structure which is electrically connected to the common source line via the channel portion and is on an opposite side of the common source line to the first gate structure.

### CROSS-REFERENCE TO RELATED APPLICATIONS

This application claims the benefit of Korean Patent Application No. 10-2010-0025872, filed on Mar. 23, 2010, the disclosure of which is hereby incorporated by reference herein in its entirety.

### BACKGROUND

(i) Technical Field

The inventive concept relates to semiconductor devices, and more particularly, to a vertically stacked fusion semiconductor device including both a non-volatile memory device and a dynamic random access memory (DRAM) device.

(ii) Description of the Related Art

Although electronic products have become smaller in size, they still may require high-capacity data processing. Accordingly, the size of semiconductor devices used in such electronic products should be reduced and device integration should also be improved. In this regard, stacked type semiconductor devices instead of conventional planar-type semiconductor devices are being considered. In addition, the demand for combination-type semiconductor devices including nonvolatile memory devices and DRAM devices is increasing.

### SUMMARY

According to an aspect of the inventive concept, there is provided a vertically stacked fusion semiconductor device including: a channel portion which extends in a first direction with respect to a surface of a semiconductor layer, a common source line which extends in a second direction different from the first direction and is electrically connected to the channel portion, a first gate structure which is electrically connected to the common source line via the channel portion and a second gate structure which is electrically connected to the common source line via the channel portion and is on an opposite side of the common source line to the first gate structure.

In some embodiments of the inventive concept, the vertically stacked fusion semiconductor device may further include: a first bit line which is electrically connected to the first gate structure and a second bit line which is spaced apart from the first bit line and electrically connected to the second gate structure. The first bit line and the second bit line may be on opposite sides of the common source line. The first bit line, the second bit line, or both the first and second bit lines may extend in a third direction having a predetermined angle with respect to the second direction.

In some embodiments of the inventive concept, the first gate structure or the second gate structure may be disposed over the common source line as viewed from the semiconductor layer. The remaining gate structure may be disposed under the common source line as viewed from the semiconductor layer.

In some embodiments of the inventive concept, at least one selected from the group consisting of the first gate structure, the second gate structure, and the common source line may surround the channel portion.

In some embodiments of the inventive concept, each of interlayer insulation layers may be interposed between the common source line and the first gate structure and between the common source line and the second gate structure.

In some embodiments of the inventive concept, a part of the channel portion may include a high-concentration ion-implantation region. A part of the channel portion may include a storage region which stores charges.

In some embodiments of the inventive concept, the first gate structure and the second gate structure may be different types of memory devices from one another. One of the first gate structure and the second gate structure may be a nonvolatile memory device and the other may be a dynamic random access memory (DRAM) device. The nonvolatile memory device may include a tunneling insulation layer, a charge storage layer, a blocking insulation layer, and a first gate electrode layer. The tunneling insulation layer, the charge storage layer, the blocking insulation layer, and the first gate electrode layer may be sequentially stacked on a sidewall of the channel portion. The DRAM device may include a gate insulation layer and a second gate electrode layer. The gate insulation layer and the second gate electrode layer may be sequentially stacked on the sidewall of the channel portion.

In some embodiments of the inventive concept, the first gate structure, the second gate structure, or both the first and second gate structures may extend in the second direction.

In some embodiments of the inventive concept, a cross-section of the channel portion may have a circular or polygonal shape.

In some embodiments of the inventive concept, the first and second directions may be perpendicular to each other.

According to another aspect of the inventive concept, there is provided a vertically stacked fusion semiconductor device including: a channel portion which extends in a direction perpendicular to a surface of a semiconductor layer and includes a high-concentration ion-implantation region adjacent to the surface of the semiconductor layer, a lower bit line which is disposed on the semiconductor layer and is electrically connected to the channel portion via the high-concentration ion-implantation region, a dynamic random access memory (DRAM) structure which is disposed on the lower bit line and is electrically connected to the lower bit line via the channel portion, a common source line which is disposed on the DRAM structure and is electrically connected to the DRAM structure via the channel portion, a non-volatile memory structure which is disposed on the common source line and is electrically connected to the common source line via the channel portion and an upper bit line which is disposed on the non-volatile memory structure and is electrically connected to the non-volatile memory structure via the channel portion.

According to another aspect of the inventive concept, there is provided a vertically stacked fusion semiconductor device including: a common source line, a pair of gate structures which are electrically connected to the common source line and include different types of memory devices and a pair of bit lines which are electrically connected to the gate structures, respectively.

According to another aspect of the inventive concept, a vertically stacked fusion semiconductor device is provided. The device includes a semiconductor layer including a first buried insulation layer and a second buried insulation layer, a channel portion that extends in a first direction perpendicular to a top surface of the semiconductor layer. A cross-section of the channel portion has one of a circular shape or polygonal shape. In addition, a part of the channel portion includes a high-concentration ion implantation region adjacent to the semiconductor layer and a storage region for storing charges adjacent to the high concentration ion implantation region. The device further includes a common source line extending in a second direction perpendicular to the first direction and wherein the common source line is electrically connected to the channel portion, a first gate structure disposed over the common source line as viewed from the semiconductor layer and which is electrically connected to the common source line via the channel portion. The first gate structure is a non-volatile memory device comprising a tunneling insulation layer, a charge storage layer, a blocking insulation layer and a first gate electrode layer sequentially stacked on a sidewall of the channel portion. The device further includes a second gate structure disposed under the common source line as viewed from the semiconductor layer and which is electrically connected to the common source line via the channel portion. The second gate structure is a dynamic random access memory (DRAM) device including a gate insulation layer and a second gate electrode layer sequentially disposed on a sidewall of the channel portion. At least one of the first gate structure, the common source line, and the second gate structure surround the channel portion. The device further includes a plurality of first bit lines disposed on an upper surface of the channel portion and on the first gate structure and which are electrically connected to the first gate structure via the channel portion and a plurality of second bit lines disposed on the second buried insulation layer of semiconductor layer, spaced apart from the plurality of first bit lines and disposed on opposite sides of the common source line to the first bit lines. The second bit lines are electrically connected to the second gate structure via the channel portion, and the second bit lines, the second gate structure, the common source line and the first gate structure are sequentially stacked on sidewalls of the channel portion in the first direction starting from the semiconductor layer. In addition, the device further includes a plurality of interlayer insulation patterns disposed between the second bit lines, the second gate structure, the common source line, the first gate structure and the first bit lines. At least one of the first gate structure and the second gate structure extends in the second direction and wherein the second bit lines and the first bit lines extend in a third direction which is perpendicular to the second direction.

### BRIEF DESCRIPTION OF THE DRAWINGS

Exemplary embodiments of the inventive concept will be more clearly understood from the following detailed description taken in conjunction with the accompanying drawings in which:

FIG. 1 is a circuit diagram of a vertically stacked fusion semiconductor device according to an exemplary embodiment of the present invention;

FIG. 2 is a perspective view of a vertically stacked fusion semiconductor device according to an exemplary embodiment of the present invention; and

FIGS. 3A through 3P are perspective views illustrating a method of fabricating the vertically stacked fusion semiconductor device according to the exemplary embodiment of the present invention illustrated in FIG. 2.

### DETAILED DESCRIPTION OF THE EXEMPLARY EMBODIMENTS

Reference will now be made in detail to exemplary embodiments, examples of which are illustrated in the accompanying drawings. However, exemplary embodiments are not limited to the embodiments illustrated hereinafter, and the embodiments herein are rather introduced to provide easy and complete understanding of the scope and spirit of exemplary embodiments. In the drawings, the thicknesses of layers and regions are exaggerated for clarity.

It will be understood that when an element, such as a layer, a region, or a substrate, is referred to as being “on,” “connected to” or “coupled to” another element, it may be directly on, connected or coupled to the other element or intervening elements may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of exemplary embodiments.

Spatially relative terms, such as “above,” “upper,” “beneath,” “below,” “lower,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “above” may encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of exemplary embodiments. As used herein, the singular forms “a,” “an” and “the” are intended to include the plural forms as well, unless the context clearly indicates otherwise. It will be further understood that the terms “comprises” and/or “comprising” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but may be to include deviations in shapes that result, for example, from manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes may be not intended to illustrate the actual shape of a region of a device and are not intended to limit the scope of exemplary embodiments.

Unless otherwise defined, all terms (including technical and scientific terms) used herein have the same meaning as commonly understood by one of ordinary skill in the art to which exemplary embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

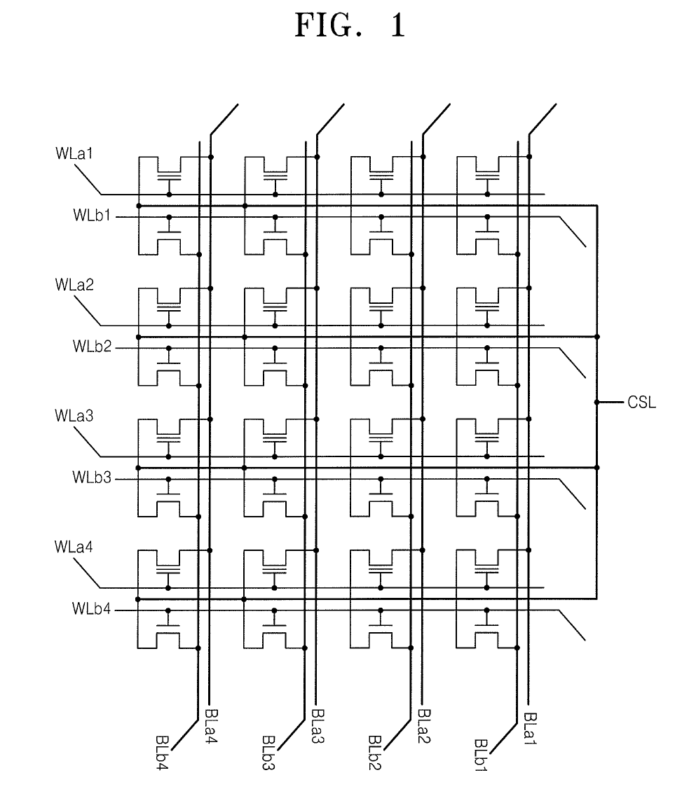

FIG. 1 is a circuit diagram of a vertically stacked fusion semiconductor device according to some embodiments of the present invention.

Referring to FIG. 1, a plurality of gate structures are electrically connected to a common source line CSL. The gate structures may be different types of memory devices such as, for example, non-volatile memory devices and dynamic random access memory (DRAM) devices. The non-volatile memory devices may be connected to first word lines WLa1, WLa2, WLa3, and WLa4, and the DRAM devices may be connected to second word lines WLb1, WLb2, WLb3, and WLb4. The non-volatile memory devices and the DRAM devices may be connected to first bit lines BLa1, BLa2, BLa3, and BLa4 and second bit lines BLb1, BLb2, BLb3, and BLb4, respectively. Thus, a pair of a non-volatile memory device and a DRAM device may be connected to different word lines and different bit lines. As the vertically stacked fusion semiconductor device includes both DRAM devices and non-volatile memory devices, the vertically stacked fusion semiconductor device may operate as a DRAM device or a non-volatile memory device according to the magnitude of a voltage applied as a gate voltage. For example, as a gate voltage for operating a DRAM device is generally lower than that for operating a non-volatile memory device, a specific voltage between the gate voltages is set to be a reference voltage and, if the DRAM device is operated, a voltage lower than the reference voltage may be applied, and if the non-volatile memory device is operated, a voltage higher than the reference voltage may be applied.

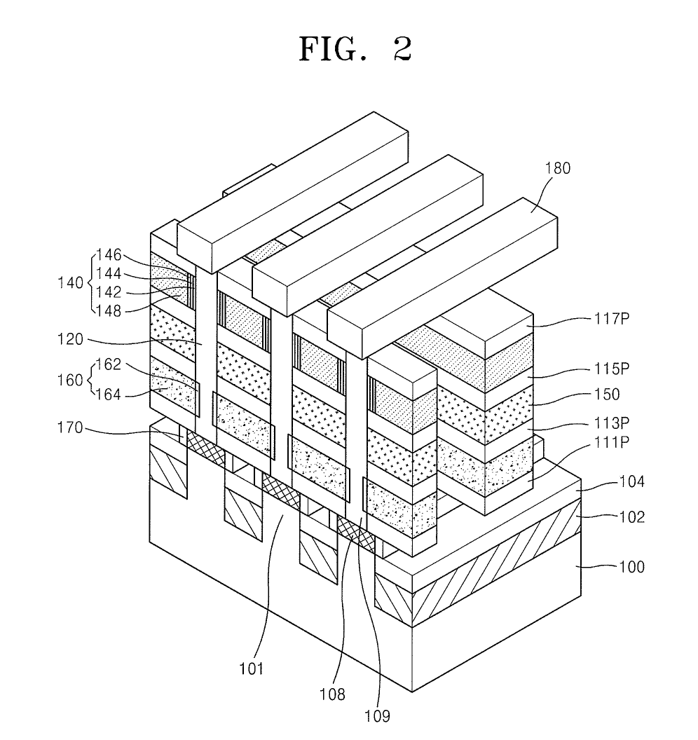

FIG. 2 is a perspective view of a vertically stacked fusion semiconductor device according to embodiments of the present invention.

Referring to FIG. 2, the vertically stacked fusion semiconductor device includes a semiconductor layer 100, a channel portion 120, a first gate structure 140, a common source line 150, and a second gate structure 160. The vertically stacked fusion semiconductor device may further include second bit lines 170 and first bit lines 180.

The semiconductor layer 100 may include a substrate including a semiconductor material, such as, for example, silicon, silicon-germanium, or the like, an epitaxial layer, a silicon-on-insulator (SOI) layer, and/or a semiconductor-on-insulator (SEOI) layer. The semiconductor layer 100 may include a first buried insulation layer 102 and a second buried insulation layer 104 that may serve as isolation layers.

The channel portion 120 extends in a first direction with respect to the surface of the semiconductor layer 100. The first direction may be a direction perpendicular to the surface of the semiconductor layer 100. A cross-section of channel portion 120 may have, for example, a circular or polygonal shape. A part of the channel portion 120 may include a high-concentration ion-implantation region 108. The high-concentration ion-implantation region 108 may be adjacent to the surface of the semiconductor layer 100. A part of the channel portion 120 that is adjacent to the high-concentration ion-implantation region 108 may include a storage region 109 for storing charges such as, for example, holes. The storage region 109 may act as a capacitor for DRAM devices. Accordingly, a DRAM device without a conventional capacitor structure, e.g. a capacitorless DRAM device, may be obtained.

The second bit lines 170, the second gate structure 160, the common source line 150, and the first gate structure 140 may be sequentially stacked on sidewalls of the channel portion 120 in the first direction starting from the semiconductor layer 100. At least one selected from the group consisting of the first gate structure 140, the common source line 150, and the second gate structure 160 may surround the channel portion 120. The first bit lines 180 may be disposed on the upper surface of the channel portion 120 and on the first gate structure 140. Interlayer insulation layer patterns 111P, 113P, 115P, and 117P may be disposed between the second bit lines 170, the second gate structure 160, the common source line 150, the first gate structure 140, and the first bit lines 180.

The common source line 150 may be electrically connected to the channel portion 120. The first gate structure 140 may be electrically connected to the common source line 150 via the channel portion 120. The first gate structure 140 may also be electrically connected to the first bit line 180 via the channel portion 120. The second gate structure 160 may be electrically connected to the common source line 150 via the channel portion 120. The second gate structure 160 may also be electrically connected to the second bit lines 170 via the channel portion 120.

The first gate structure 140 and the second gate structure 160 may be on opposite sides of the common source line 150. For example, the first gate structure 140 may be disposed over the common source line 150 as viewed from the semiconductor layer 100 and the second gate structure 160 may be disposed under the common source line 150 as viewed from the semiconductor layer 100. The second bit lines 170 and the first bit lines 180 may also be separated from each other. The second bit lines 170 and the first bit lines 180 may be on opposite sides of the common source line 150. At least one selected from the group consisting of the first gate structure 140, the common source line 150, and the second gate structure 160 may extend in a second direction different from the first direction. For example, the first and second directions may be perpendicular to each other. Both the second bit lines 170 and the first bit lines 180 may extend in a third direction at a predetermined angle to the second direction. The third direction may be perpendicular to the second direction.

The first gate structure 140 and the second gate structure 160 may be different types of memory devices. For example, either the first gate structure 140 or the second gate structure 160 may be a non-volatile memory device, and the remaining one may be a DRAM device. Although the first gate structure 140 is a non-volatile memory device and the second gate structure 160 is a DRAM device in FIG. 2, the present invention is not limited thereto.

When the first gate structure 140 is a non-volatile memory device, the first gate structure 140 may include a tunneling insulation layer 142, a charge storage layer 144, a blocking insulation layer 146, and a first gate electrode layer 148. The tunneling insulation layer 142, the charge storage layer 144, the blocking insulation layer 146, and the first gate electrode layer 148 may be sequentially disposed on sidewalls of the channel portion 120.

When the second gate structure 160 is a DRAM device, the second gate structure 160 may include a gate insulation layer 162 and a second gate electrode layer 164. The gate insulation layer 162 and the second gate electrode layer 164 may be sequentially disposed on the sidewalls of the channel portion 120.

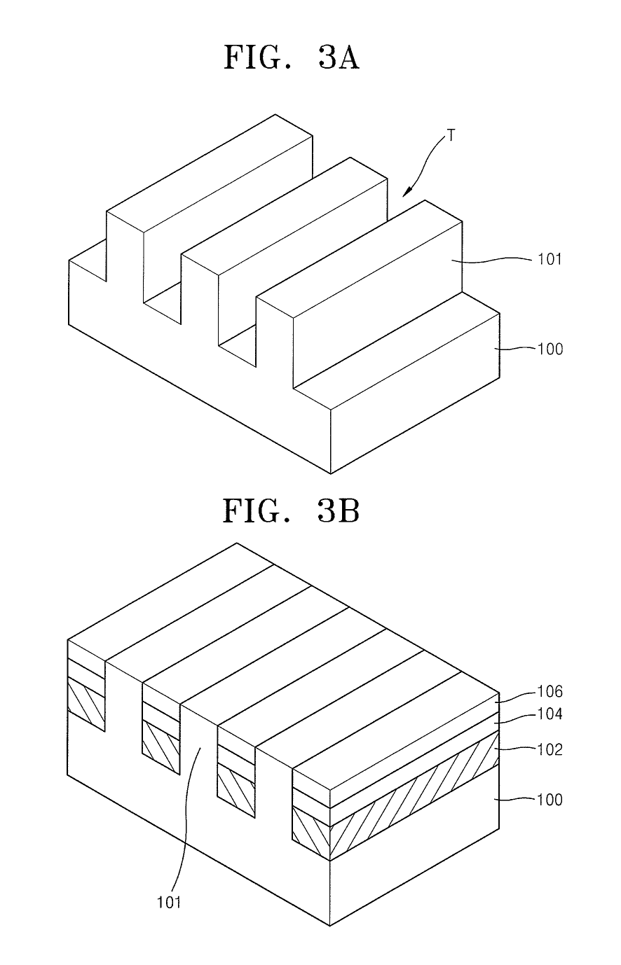

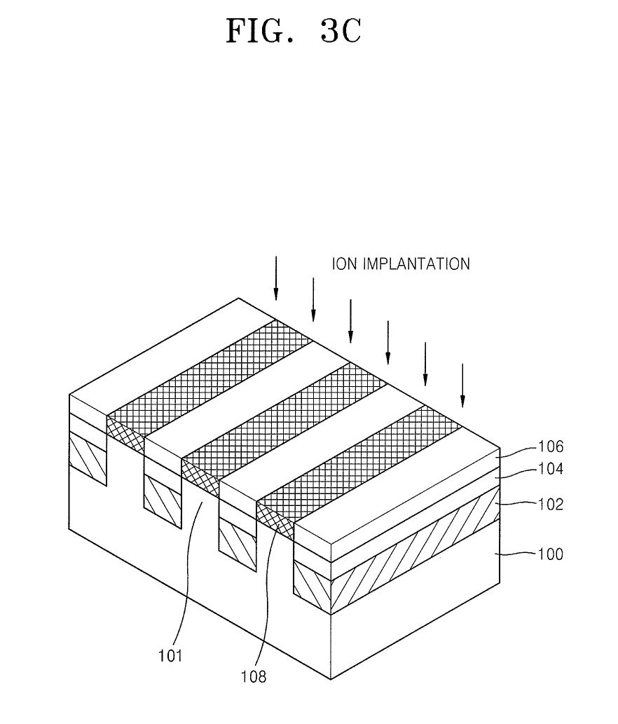

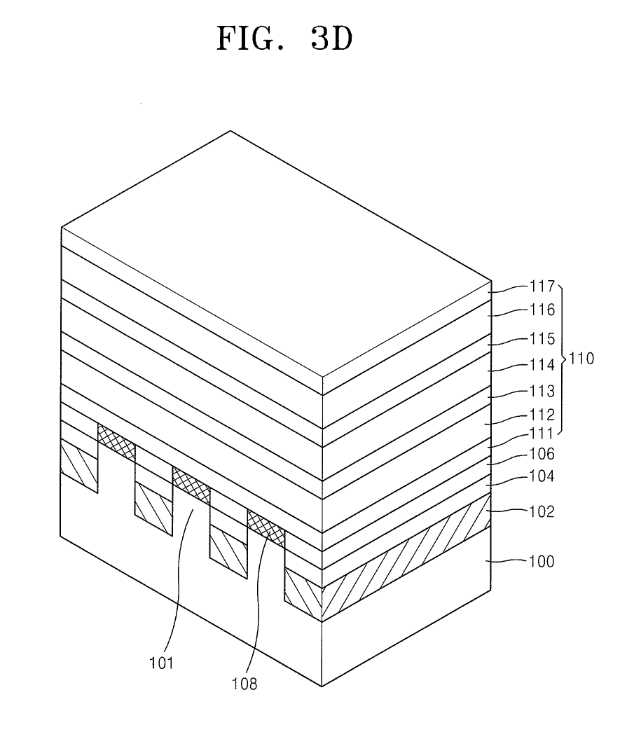

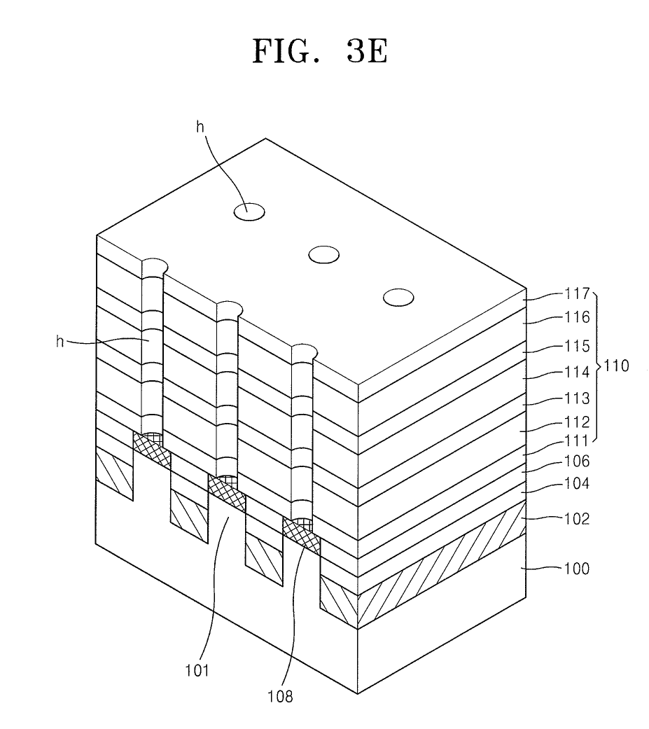

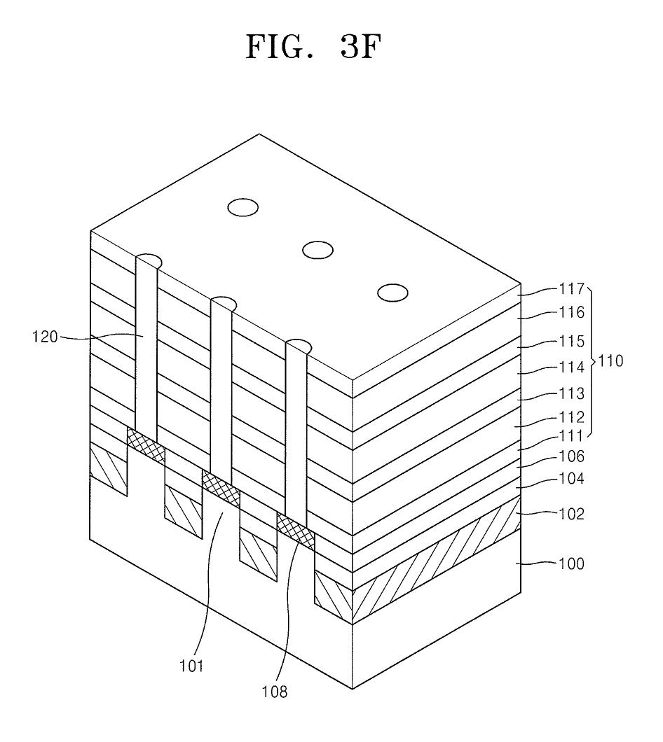

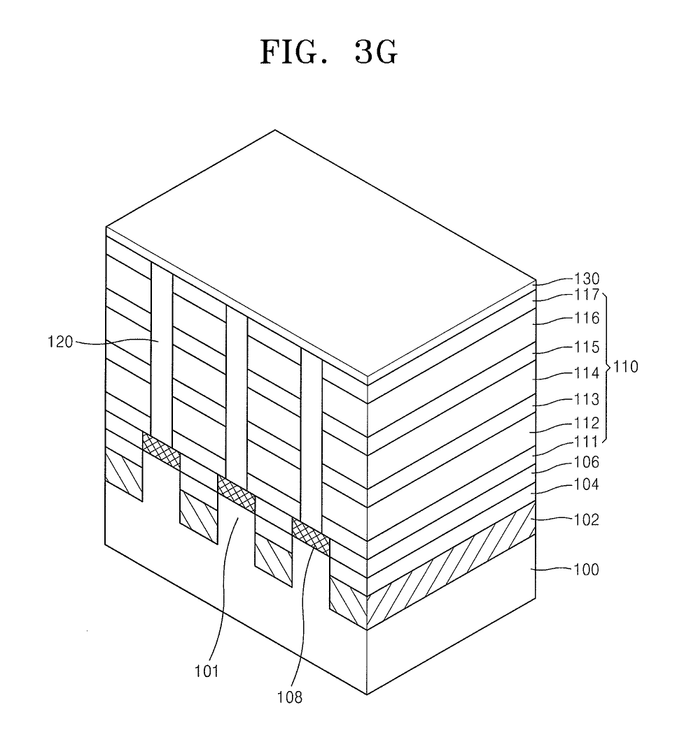

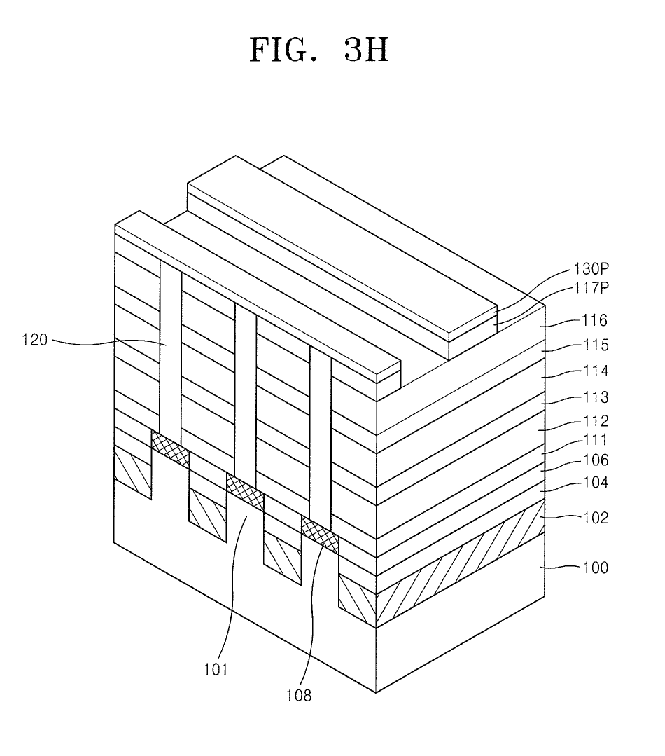

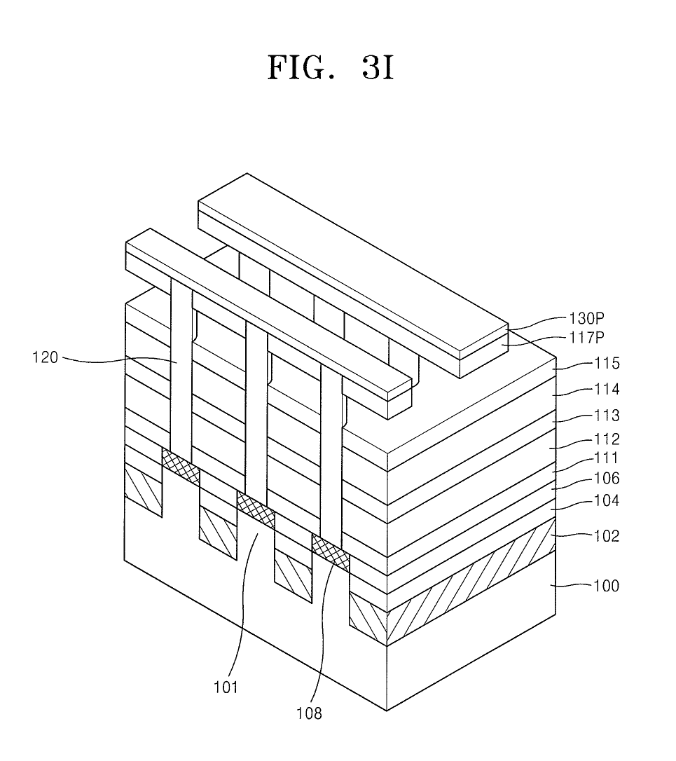

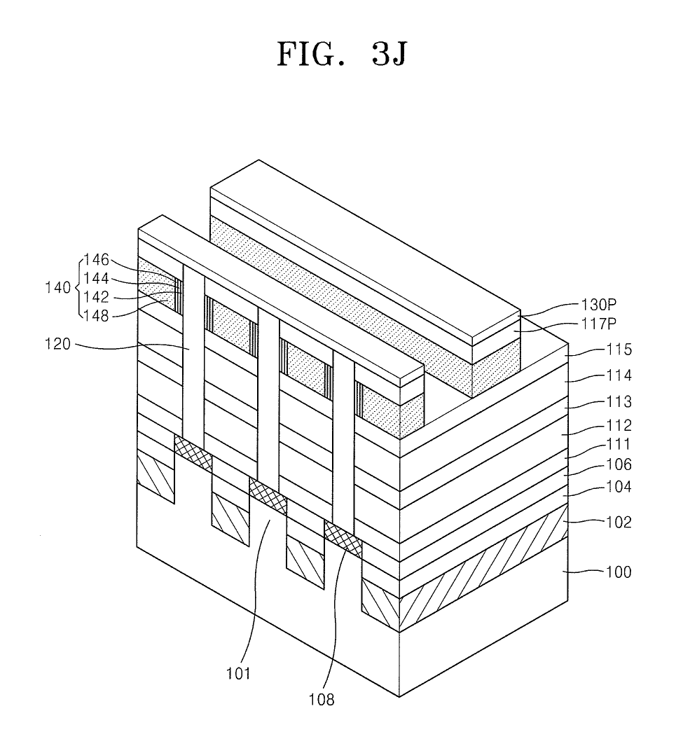

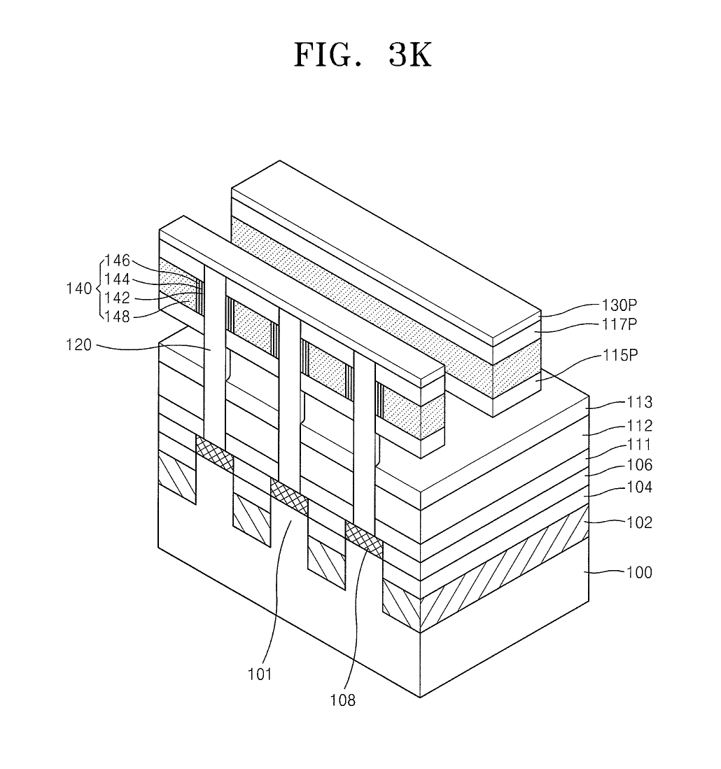

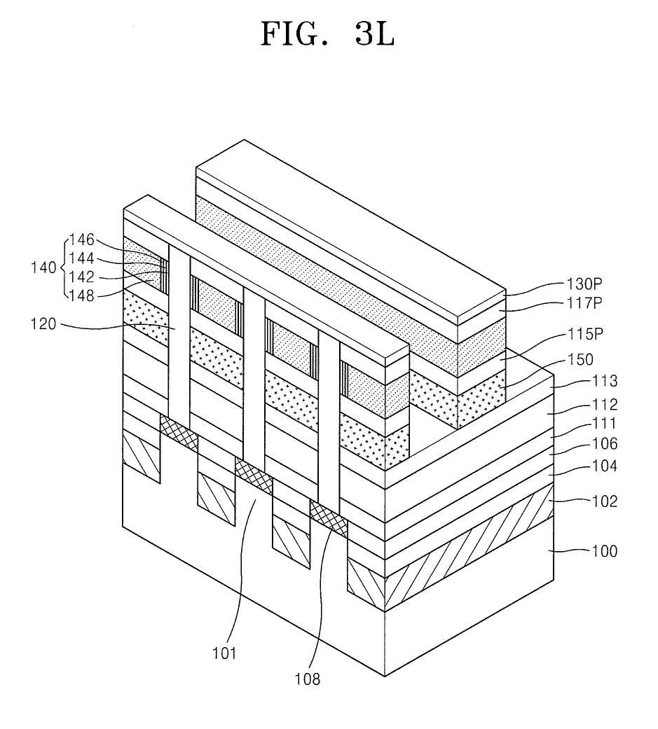

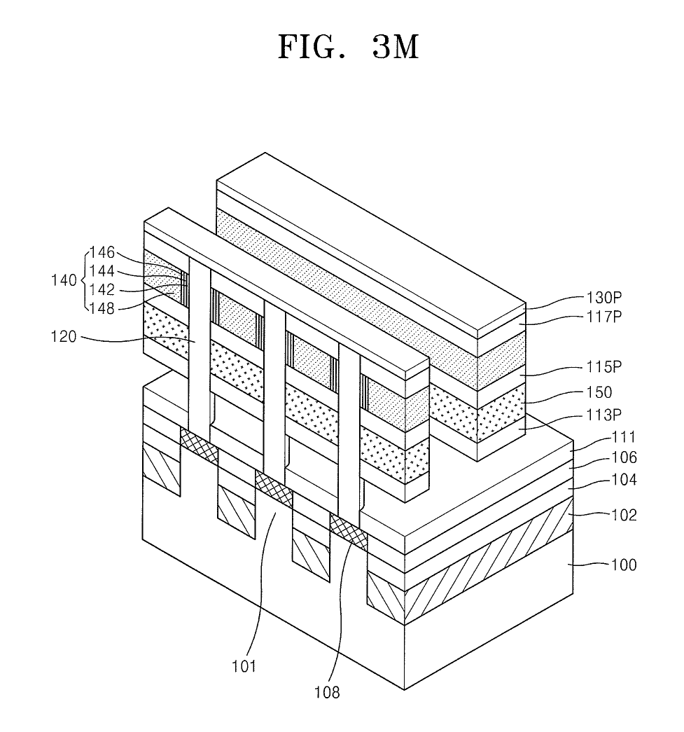

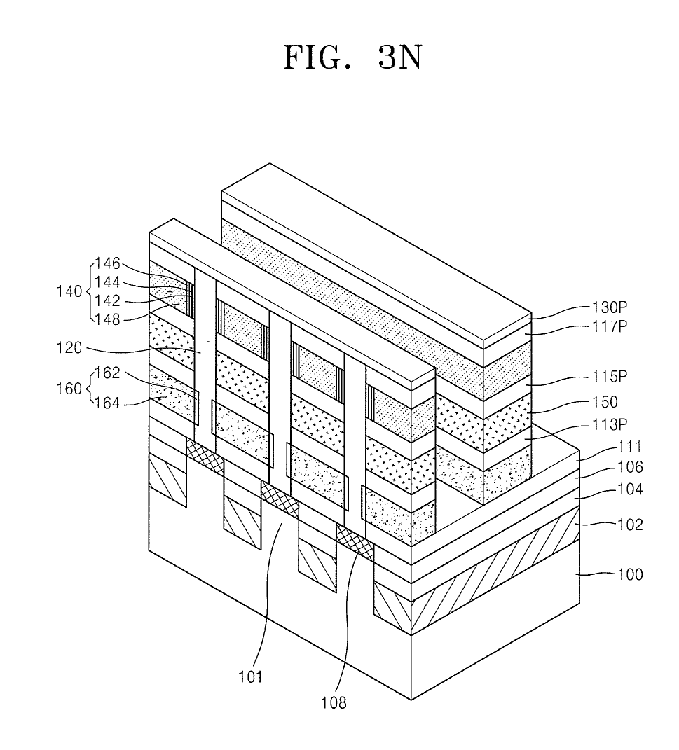

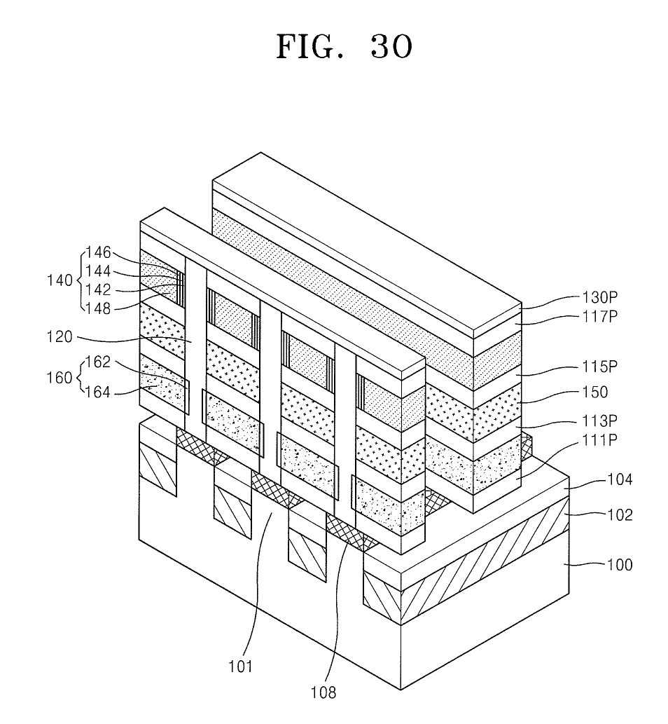

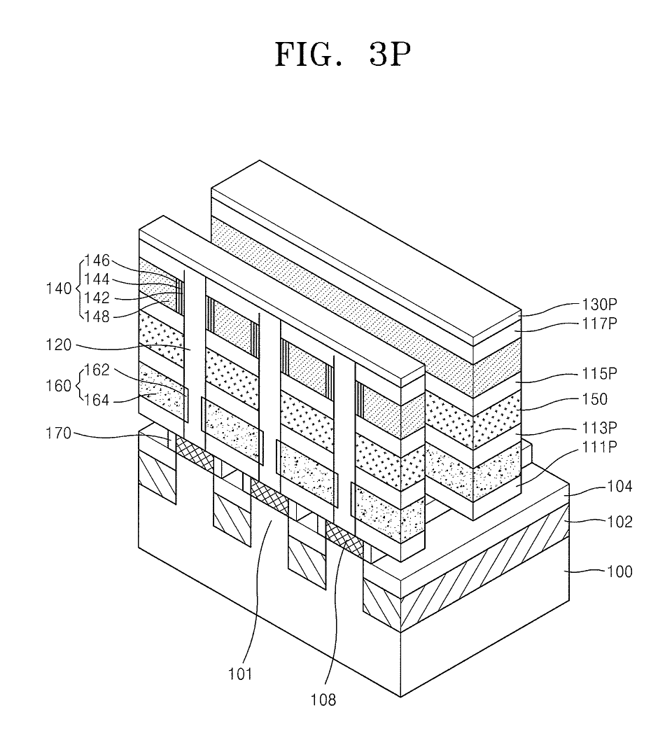

FIGS. 3A through 3P are perspective views illustrating a method of fabricating the vertically stacked fusion semiconductor device according to the embodiments of the present invention illustrated in FIG. 2.

Referring to FIG. 3A, the semiconductor layer 100 is provided. Trenches T are formed by removing a part of the semiconductor layer 100. Although not shown in FIG. 3A, the trenches T may be formed by disposing a mask pattern layer (not shown) on the semiconductor layer 100 and then etching an exposed region of the semiconductor layer 100 by using the mask pattern layer as an etch mask. Accordingly, the semiconductor layer 100 may include protrusions 101.

Referring to FIG. 3B, a plurality of layers, for example, the first buried insulation layer 102, the second buried insulation layer 104, and a buried sacrificial layer 106, are formed between the protrusions 101 so as to bury the trenches T. The first buried insulation layer 102 and the second buried insulation layer 104 may perform the function of a trench type isolation film. The first buried insulation layer 102, the second buried insulation layer 104, and the buried sacrificial layer 106 may be formed by, for example, Chemical Vapor Deposition (CVD), Low Pressure CVD (LPCVD), Plasma Enhanced CVD (PECVD), High Density Plasma CVD (HDP CVD), Atomic Layer Deposition (ALD), sputtering, or the like. The first buried insulation layer 102, the second buried insulation layer 104, and the buried sacrificial layer 106 may include, for example, oxide, nitride, and oxynitride, respectively. Examples of the oxide may include but is not limited to silicon oxide, aluminium oxide, hafnium oxide, hafnium silicon oxide, hafnium aluminium oxide, zirconium oxide, tantalum oxide, hafnium tantalum oxide, lanthanum oxide, lanthanum aluminium oxide, lanthanum hafnium oxide, hafnium aluminium oxide, and metal oxide. Examples of the nitride may include silicon nitride, aluminium nitride, hafnium nitride, hafnium silicon nitride, hafnium aluminium nitride, zirconium nitride, tantalum nitride, hafnium tantalum nitride, lanthanum nitride, lanthanum aluminium nitride, lanthanum hafnium nitride, hafnium aluminium nitride, and metal nitride. Examples of the oxinitride include, but are not limited to silicon oxinitride, aluminium oxinitride, hafnium oxinitride, hafnium silicon oxinitride, hafnium aluminium oxinitride, zirconium oxinitride, tantalum oxinitride, hafnium tantalum oxinitride, lanthanum oxinitride, lanthanum aluminium oxinitride, lanthanum hafnium oxinitride, hafnium aluminium oxinitride, and metal oxinitride. The first buried insulation layer 102 and the second buried insulation layer 104 may have different etch selectivities. The second buried insulation layer 104 and the buried sacrificial layer 106 may also have different etching selectivities. For example, the second buried insulation layer 104 may include but is not limited to silicon nitride, and the buried sacrificial layer 106 may include a material having an etch selectivity different from that of the silicon nitride, for example, silicon oxide.

Referring to FIG. 3C, the high-concentration ion-implantation region 108 is formed by implanting ions into the protrusions 101. The ions may include, but are not limited to a Group III element or a Group V element, and thus the high-concentration ion-implantation region 108 may be a p-type or n-type ion-implantation region. The depth of the high-concentration ion-implantation region 108 toward the semiconductor layer 100 illustrated in FIG. 3C is an example, and the present invention is not limited thereto. In other words, the high-concentration ion-implantation region 108 may have a depth that ranges from the depth of the buried sacrificial layer 106 to that of the second buried insulation layer 104.

Referring to FIG. 3D, a stacked layer 110 in which first, second, third, and fourth interlayer insulation layers 111, 113, 115, and 117 alternate with first, second, and third sacrificial layers 112, 114, and 116 is formed. In other words, the first interlayer insulation layer 111, the first sacrificial layer 112, the second interlayer insulation layer 113, the second sacrificial layer 114, the third interlayer insulation layer 115, the third sacrificial layer 116, and the fourth interlayer insulation layer 117 are sequentially formed on the buried sacrificial layer 106 and the high-concentration ion-implantation region 108. The first through fourth interlayer insulation layers 111, 113, 115, and 117 and the first through third sacrificial layers 112, 114, and 116 may be formed by, for example, CVD, LPCVD, HDP CVD, PECVD, ALD, sputtering, or the like. Each of the first through fourth interlayer insulation layers 111, 113, 115, and 117 and the first through third sacrificial layers 112, 114, and 116 may include, for example, oxide, nitride, or oxynitride. Examples of the oxide may include but are not limited to silicon oxide, aluminium oxide, hafnium oxide, hafnium silicon oxide, hafnium aluminium oxide, zirconium oxide, tantalum oxide, hafnium tantalum oxide, lanthanum oxide, lanthanum aluminium oxide, lanthanum hafnium oxide, hafnium aluminium oxide, and metal oxide. Examples of the nitride may include but are not limited to silicon nitride, aluminium nitride, hafnium nitride, hafnium silicon nitride, hafnium aluminium nitride, zirconium nitride, tantalum nitride, hafnium tantalum nitride, lanthanum nitride, lanthanum aluminium nitride, lanthanum hafnium nitride, hafnium aluminium nitride, and metal nitride. Examples of the oxinitride may include but are not limited to silicon oxinitride, aluminium oxinitride, hafnium oxinitride, hafnium silicon oxinitride, hafnium aluminium oxinitride, zirconium oxinitride, tantalum oxinitride, hafnium tantalum oxinitride, lanthanum oxinitride, lanthanum aluminium oxinitride, lanthanum hafnium oxinitride, hafnium aluminium oxinitride, and metal oxinitride. In the first through fourth interlayer insulation layers 111, 113, 115, and 117 and the first through third sacrificial layers 112, 114, and 116, adjacent layers may have different etch selectivities. For example, the first interlayer insulation layer 111 may have an etch selectivity different from that of the first sacrificial layer 112, and the second interlayer insulation layer 113 may have an etch selectivity different from those of the first sacrificial layer 112 and the second sacrificial layer 114. For example, the first through fourth interlayer insulation layers 111, 113, 115, and 117 may include silicon nitride, and the first through third sacrificial layers 112, 114, and 116 may include a material having an etch selectivity different from that of the silicon nitride, for example, silicon oxide.

Referring to FIG. 3E, openings h through which the high-concentration ion-implantation region 108 is exposed are formed by removing parts of the stacked layer 110. In other words, the openings h expose the high-concentration ion-implantation region 108 by penetrating the first through fourth interlayer insulation layers 111, 113, 115, and 117 and the first through third sacrificial layers 112, 114, and 116. A cross-section of openings h may have, for example, circular or polygonal shapes.

Referring to FIG. 3F, the channel portion 120 is formed in the openings h. The channel portion 120 may include, for example, silicon, silicon-germanium, or germanium. The channel portion 120 may be, for example, a single crystal layer that has been epitaxially grown from the semiconductor layer 100. Alternatively, the channel portion 120 may be formed by, for example, first growing an amorphous layer or a polycrystal layer and then phase-transforming the amorphous layer or the polycrystal layer into a single crystal layer by using a furnace or a laser. If necessary, the channel portion 120 may be doped with, for example, a Group III element or a Group V element. In this case, a doped concentration of the channel portion 120 may be lower than an ion concentration of the high-concentration ion-implantation region 108.

Referring to FIG. 3G, a mask layer 130 is formed on the stacked layer 110. The mask layer 130 may be a photoresist layer or a hard mask layer, and for example, may include silicon nitride. The mask layer 130 may include the same material as that used to form the fourth interlayer insulation layer 117.

Referring to FIG. 3H, the mask layer 130 is patterned to form a mask pattern 130P. Then, some regions of the fourth interlayer insulation layer 117 are removed to form a fourth interlayer insulation layer pattern 117P. At this time, some regions of the fourth interlayer insulation layer 117 may be etched using the mask pattern 130P as an etch mask. This etching may be wet etching or dry etching. For example, the etching may be dry etching. When the mask layer 130 and the fourth interlayer insulation layer 117 include the same material, the fourth interlayer insulation layer 117 may be patterned simultaneously when the mask layer 130 is patterned. On the other hand, as the fourth interlayer insulation layer 117 and the third sacrificial layer 116 may have different etch selectivities as described above, the third sacrificial layer 116 may not be etched while the fourth interlayer insulation layer 117 is being patterned. Thus, an upper surface of the third sacrificial layer 116 is exposed by the fourth interlayer insulation layer pattern 117P.

Referring to FIG. 3I, the third sacrificial layer 116 is etched away so that the channel portion 120 is exposed in a lateral direction and a part of the upper surface of the third interlayer insulation layer 115 is exposed. The third sacrificial layer 116 may be completely removed. This etching may be wet etching or dry etching. For example, the etching may be wet etching. As the third sacrificial layer 116 may have an etch selectivity different from those of the fourth interlayer insulation layer pattern 117P and the third interlayer insulation layer 115 as described above, the fourth interlayer insulation layer pattern 117P and the third interlayer insulation layer 115 may not be etched away while the third sacrificial layer 116 is being removed.

Referring to FIG. 3J, the first gate structure 140 may be formed on the exposed part of the channel portion 120 and between the fourth interlayer insulation layer pattern 117P and the third interlayer insulation layer 115. In other words, the first gate structure 140 may be formed within a region from which the third sacrificial layer 116 has been removed. The first gate structure 140 may include the tunneling insulation layer 142, the charge storage layer 144, the blocking insulation layer 146, and the first gate electrode layer 148. The first gate structure 140 may have a pattern corresponding to the patterns of the mask pattern 130P and the fourth interlayer insulation layer pattern 117P, which are identical to each other.

The tunneling insulation layer 142 may be formed by, for example, oxidizing the channel portion 120 according to thermal oxidization. Alternatively, the tunneling insulation layer 142 may be formed by, for example, CVD or the like. For example, the tunneling insulation layer 142 may be a single layer or a multi-layer each including at least one selected from the group consisting of silicon oxide (SiO₂), silicon nitride (Si₃N₄), silicon oxynitride (SiON), hafnium oxide (HfO₂), hafnium silicon oxide (HfSixOy), aluminium oxide (Al₂O₃), and zirconium oxide (ZrO₂). Although the tunneling insulation layer 142 is located on the channel portion 120 in the present embodiment, the present invention is not limited thereto. In other words, the tunneling insulation layer 142 may be formed within the channel portion 120.

The charge storage layer 144 may be a floating gate or a charge trapping layer. When the charge storage layer 144 is a floating gate, polysilicon may be deposited by CVD, for example, LPCVD in which PH₃ gas and either SiH₄ or Si₂H₆ gas are used. When the charge storage layer 144 is a charge trapping layer, the charge storage layer 144 may be a single layer or a multi-layer each including, for example, at least one selected from the group consisting of silicon oxide (SiO₂), silicon nitride (Si₃N₄), silicon oxynitride (SiON), hafnium oxide (HfO₂), zirconium oxide (ZrO₂), tantalum oxide (Ta₂O₃), titanium oxide (TiO₂), hafnium aluminium oxide (HfAlxOy), hafnium tantalum oxide (HfTaxOy), hafnium silicon oxide (HfSixOy), aluminum nitride (AlxNy), and aluminium gallium nitride (AlGaN).

The blocking insulation layer 146 may be a single layer including at least one selected from the group consisting of, for example, silicon oxide (SiO₂), silicon nitride (Si₃N₄), silicon oxynitride (SiON), and a high-k dielectric material, or a composite layer obtained by stacking a plurality of layers each including at least one selected from the group consisting of the aforementioned materials. The high-k dielectric material may include at least one selected from the group consisting of, for example, aluminium oxide (Al₂O₃), tantalum oxide (Ta₂O₃), titanium oxide (TiO₂), yttrium oxide (Y₂O₃), zirconium oxide (ZrO₂), zirconium silicon oxide (ZrSixOy), hafnium oxide (HfO₂), hafnium silicon oxide (HfSixOy), lanthanum oxide (La₂O₃), lanthanum aluminium oxide (LaAlxOy), lanthanum hafnium oxide (LaHfxOy), hafnium aluminium oxide (HfAlxOy), and praseodymium oxide (Pr₂O₃).

The first gate electrode layer 148 may be a single layer including at least one selected from the group consisting of, for example, polysilicon, aluminium (Al), gold (Au), beryllium (Be), bismuth (Bi), cobalt (Co), hafnium (Hf), indium (In), manganese (Mn), molybdenum (Mo), nickel (Ni), lead (Pb), palladium (Pd), platinum (Pt), rhodium (Rh), rhenium (Re), ruthenium (Ru), tantalum (Ta), thulium (Te), titanium (Ti), tungsten (W), zinc (Zn), zirconium (Zr), a nitride of one or more of these materials, and a silicide of one or more of these materials, or a multi-layer obtained by stacking a plurality of layers each including at least one selected from the group consisting of the aforementioned materials.

However, the tunneling insulation layer 142, the charge storage layer 144, the blocking insulation layer 146, and the first gate electrode layer 148 described above are just examples, and the present invention is not limited thereto.

The first gate structure 140 may be formed by gate replacement. Accordingly, in contrast with a process of forming a gate structure by general photolithographic etching, an edge of the tunneling insulation layer 142 may not be damaged. In addition, after the first gate structure 140 is formed, a damage curing process such as, for example, re-oxidization may not be required.

Referring to FIG. 3K, some regions of the third interlayer insulation layer 115 are removed to form the third interlayer insulation layer pattern 115P. At this time, the third interlayer insulation layer pattern 115P may be formed by etching some regions of the third interlayer insulation layer 115 by using the mask pattern 130P as an etch mask. This etching may be wet etching or dry etching. For example, the etching may be dry etching. As the third interlayer insulation layer 115 and the second sacrificial layer 114 may have different etch selectivities as described above, the second sacrificial layer 114 may not be etched away while the third interlayer insulation layer 115 is being patterned. Accordingly, an upper surface of the second sacrificial layer 114 and a part of an upper surface of the second interlayer insulation layer 113 may be exposed by the third interlayer insulation layer pattern 115P.

Then, the second sacrificial layer 114 is etched away, and thus the channel portion 120 may be exposed in a lateral direction. The second sacrificial layer 114 may be completely removed. This etching may be wet etching or dry etching. For example, the etching may be wet etching. As the second sacrificial layer 114 may have an etch selectivity different from those of the fourth interlayer insulation layer pattern 117P, the third interlayer insulation layer pattern 115P, and the second interlayer insulation layer 113 as described above, the fourth interlayer insulation layer pattern 117P, the third interlayer insulation layer pattern 115P, and the second interlayer insulation layer 113 may not be etched away while the second sacrificial layer 114 is being removed.

Referring to FIG. 3L, the common source line 150 may be formed on the exposed part of the channel portion 120 and between the third interlayer insulation layer pattern 115P and the second interlayer insulation layer 113. In other words, the common source line 150 may be formed within a region from which the second sacrificial layer 114 has been removed. The common source line 150 may have a pattern corresponding to the patterns of the mask pattern 130P, the fourth interlayer insulation layer pattern 117P, the first gate structure 140, and the third interlayer insulation layer pattern 115P, which are identical. For example, common source line 150 may be a single layer including at least one selected from the group consisting of polysilicon, aluminium (Al), gold (Au), beryllium (Be), bismuth (Bi), cobalt (Co), hafnium (Hf), indium (In), manganese (Mn), molybdenum (Mo), nickel (Ni), lead (Pb), palladium (Pd), platinum (Pt), rhodium (Rh), rhenium (Re), ruthenium (Ru), tantalum (Ta), thulium (Te), titanium (Ti), tungsten (W), zinc (Zn), zirconium (Zr), a nitride of one or more of these materials, and a silicide of one or more of these materials, or a multi-layer obtained by stacking a plurality of layers each including at least one selected from the group consisting of the aforementioned materials.

Referring to FIG. 3M, some regions of the second interlayer insulation layer 113 are removed to form the second interlayer insulation layer pattern 113P. At this time, the second interlayer insulation layer pattern 113P may be formed by etching some regions of the second interlayer insulation layer 113 by using the mask pattern 130P as an etch mask. This etching may be wet etching or dry etching. For example, the etching may be dry etching. As the second interlayer insulation layer 113 and the first sacrificial layer 112 may have different etch selectivities as described above, the first sacrificial layer 112 may not be etched away while the second interlayer insulation layer 113 is being patterned. Accordingly, an upper surface of the first sacrificial layer 112 may be exposed by the second interlayer insulation layer pattern 113P.

Then, the first sacrificial layer 112 is etched away, and thus the channel portion 120 may be exposed in a lateral direction and a part of the upper surface of the first interlayer insulation layer 111 may be exposed. The first sacrificial layer 112 may be completely removed. This etching may be wet etching or dry etching. For example, the etching may be wet etching. As the first sacrificial layer 112 may have an etch selectivity different from those of the fourth interlayer insulation layer pattern 117P, the third interlayer insulation layer pattern 115P, the second interlayer insulation layer pattern 113P, and the first interlayer insulation layer 111 as described above, the fourth interlayer insulation layer pattern 117P, the third interlayer insulation layer pattern 115P, the second interlayer insulation layer pattern 113P, and the first interlayer insulation layer 111 may not be etched away while the first sacrificial layer 112 is being removed.

Referring to FIG. 3N, the second gate structure 160 may be formed on the exposed part of the channel portion 120 and between the second interlayer insulation layer pattern 113P and the first interlayer insulation layer 111. In other words, the second gate structure 160 may be formed within a region from which the first sacrificial layer 112 has been removed. The second gate structure 160 may include the gate insulation layer 162 and the second gate electrode layer 164. The second gate structure 160 may have a pattern corresponding to the patterns of the fourth interlayer insulation layer pattern 117P, the first gate structure 140, the third interlayer insulation layer pattern 115P, and the second interlayer insulation layer pattern 113P, which are identical to each other.

The gate insulation layer 162 may be formed by, for example, oxidizing the channel portion 120 according to thermal oxidization. Alternatively, the gate insulation layer 162 may be formed by, for example, CVD or the like. The gate insulation layer 162 may be a single layer or a multi-layer each including, for example, at least one selected from the group consisting of silicon oxide (SiO₂), silicon nitride (Si₃N₄), silicon oxynitride (SiON), hafnium oxide (HfO₂), hafnium silicon oxide (HfSixOy), aluminium oxide (Al₂O₃), and zirconium oxide (ZrO₂). Although the gate insulation layer 162 is located on the channel portion 120 in the present embodiment, the present invention is not limited thereto. In other words, the gate insulation layer 162 may be formed within the channel portion 120.

For example, the second gate electrode layer 164 may be a single layer including at least one selected from the group consisting of polysilicon, aluminium (Al), gold (Au), beryllium (Be), bismuth (Bi), cobalt (Co), hafnium (Hf), indium (In), manganese (Mn), molybdenum (Mo), nickel (Ni), lead (Pb), palladium (Pd), platinum (Pt), rhodium (Rh), rhenium (Re), ruthenium (Ru), tantalum (Ta), thulium (Te), titanium (Ti), tungsten (W), zinc (Zn), zirconium (Zr), a nitride of one or more of these materials, and a silicide of one or more of these materials, or a multi-layer obtained by stacking a plurality of layers each including at least one selected from the group consisting of the aforementioned materials.

Referring to FIG. 3O, some regions of the first interlayer insulation layer 111 are removed to form the first interlayer insulation layer pattern 111P. At this time, the first interlayer insulation layer pattern 111P may be fanned by etching the some regions of the first interlayer insulation layer 111 by using the mask pattern 130P as an etch mask. This etching may be wet etching or dry etching. For example, the etching may be dry etching. As the first interlayer insulation layer 111 and the buried sacrificial layer 106 may have different etch selectivities as described above, the buried sacrificial layer 106 may not be etched away while the first interlayer insulation layer 111 is being patterned. Accordingly, an upper surface of the buried sacrificial layer 106 may be exposed by the first interlayer insulation layer pattern 111P.

Then, the buried sacrificial layer 106 is etched away, and thus the high-concentration ion-implantation region 108 may be exposed in a lateral direction and a part of the upper surface of the second buried insulation layer 104 may be exposed. The buried sacrificial layer 106 may be completely removed. This etching may be wet etching or dry etching. For example, the etching may be wet etching. As the buried sacrificial layer 106 may have an etch selectivity different from those of the fourth interlayer insulation layer pattern 117P, the third interlayer insulation layer pattern 115P, the second interlayer insulation layer pattern 113P, the first interlayer insulation layer pattern 111P, and the second buried insulation layer 104 as described above, the fourth interlayer insulation layer pattern 117P, the third interlayer insulation layer pattern 115P, the second interlayer insulation layer pattern 113P, the first interlayer insulation layer pattern 111P, and the second buried insulation layer 104 may not be etched away while the buried sacrificial layer 106 is being removed.

Referring to FIG. 3P, the second bit lines 170 may be formed on the exposed part of the high-concentration ion-implantation region 108 and between the first interlayer insulation layer pattern 111P and the second buried insulation layer 104. The second bit lines 170 may be electrically connected to the high-concentration ion-implantation region 108. Then, the mask pattern 130P is removed to form the first bit lines 180 on the fourth interlayer insulation layer pattern 117P, thereby completing the fabrication of the vertically stacked fusion semiconductor device of FIG. 2. The first bit lines 180 may be electrically connected to the channel portion 120. For example, the second bit lines 170, the first bit lines 180, or both of them may be a single layer including at least one selected from the group consisting of polysilicon, aluminium (Al), gold (Au), beryllium (Be), bismuth (Bi), cobalt (Co), hafnium (Hf), indium (In), manganese (Mn), molybdenum (Mo), nickel (Ni), lead (Pb), palladium (Pd), platinum (Pt), rhodium (Rh), rhenium (Re), ruthenium (Ru), tantalum (Ta), thulium (Te), titanium (Ti), tungsten (W), zinc (Zn), zirconium (Zr), a nitride of one or more of these materials, and a silicide of one or more of these materials, or a multi-layer obtained by stacking a plurality of layers each including at least one selected from the group consisting of the aforementioned materials.

The foregoing is illustrative of exemplary embodiments and is not to be construed as being limited thereto. Although exemplary embodiments have been described, those of ordinary skill in the art will readily appreciate that many modifications are possible in the exemplary embodiments without materially departing from the novel teachings and advantages of the exemplary embodiments. Accordingly, all such modifications are intended to be included within the scope of the claims. Exemplary embodiments are defined by the following claims, with equivalents of the claims to be included therein.

What is claimed is:

1. A vertically stacked fusion semiconductor device comprising:
a channel portion which extends in a first direction with respect to a surface of a semiconductor layer;
a common source line which extends in a second direction different from the first direction and is electrically connected to the channel portion;
a first gate structure which is electrically connected to the common source line via the channel portion; and
a second gate structure which is electrically connected to the common source line via the channel portion and is on an opposite side of the common source line to the first gate structure.

2. The vertically stacked fusion semiconductor device of claim 1, further comprising:
a first bit line which is electrically connected to the first gate structure; and
a second bit line which is spaced apart from the first bit line and electrically connected to the second gate structure.

3. The vertically stacked fusion semiconductor device of claim 2, wherein the first bit line and the second bit line are on opposite sides of the common source line.

4. The vertically stacked fusion semiconductor device of claim 2, wherein at least one of the first bit line and the second bit line extends in a third direction having a predetermined angle with respect to the second direction.

5. The vertically stacked fusion semiconductor device of claim 1, wherein one of the first gate structure and the second gate structure is disposed over the common source line as viewed from the semiconductor layer, and the other of the first gate structure and the second gate structure is disposed under the common source line as viewed from the semiconductor layer.

6. The vertically stacked fusion semiconductor device of claim 1, wherein at least one selected from the group consisting of the first gate structure, the second gate structure, and the common source line surrounds the channel portion.

7. The vertically stacked fusion semiconductor device of claim 1, wherein each of interlayer insulation layers are interposed between the common source line and the first gate structure and between the common source line and the second gate structure.

8. The vertically stacked fusion semiconductor device of claim 1, wherein a part of the channel portion comprises a high-concentration ion-implantation region.

9. The vertically stacked fusion semiconductor device of claim 1, wherein a part of the channel portion comprises a storage region which stores charges.

10. The vertically stacked fusion semiconductor device of claim 1, wherein the first gate structure and the second gate structure are different types of memory devices from one another.

11. The vertically stacked fusion semiconductor device of claim 1, wherein one of the first gate structure and the second gate structure is a nonvolatile memory device and the other of the first gate structure and the second gate structure is a dynamic random access memory (DRAM) device.

12. The vertically stacked fusion semiconductor device of claim 11, wherein the nonvolatile memory device comprises a tunneling insulation layer, a charge storage layer, a blocking insulation layer, and a first gate electrode layer.

13. The vertically stacked fusion semiconductor device of claim 12, wherein the tunneling insulation layer, the charge storage layer, the blocking insulation layer, and the first gate electrode layer are sequentially stacked on a sidewall of the channel portion.

14. The vertically stacked fusion semiconductor device of claim 11, wherein the DRAM device comprises a gate insulation layer and a second gate electrode layer.

15. The vertically stacked fusion semiconductor device of claim 14, wherein the gate insulation layer and the second gate electrode layer are sequentially stacked on a sidewall of the channel portion.

16. The vertically stacked fusion semiconductor device of claim 1, wherein at least one of the first gate structure and the second gate structure extends in the second direction.

17. The vertically stacked fusion semiconductor device of claim 1, wherein a cross-section of the channel portion has one of a circular shape or polygonal shape.

18. The vertically stacked fusion semiconductor device of claim 1, wherein the first and second directions are perpendicular to each other.

19. A vertically stacked fusion semiconductor device comprising:
a channel portion which extends in a direction perpendicular to a surface of a semiconductor layer and comprises a high-concentration ion-implantation region adjacent to the surface of the semiconductor layer;
a lower bit line which is disposed on the semiconductor layer and is electrically connected to the channel portion via the high-concentration ion-implantation region;
a dynamic random access memory (DRAM) structure which is disposed on the lower bit line and is electrically connected to the lower bit line via the channel portion;
a common source line which is disposed on the DRAM structure and is electrically connected to the DRAM structure via the channel portion;
a non-volatile memory structure which is disposed on the common source line and is electrically connected to the common source line via the channel portion; and
an upper bit line which is disposed on the non-volatile memory structure and is electrically connected to the non-volatile memory structure via the channel portion.

20. A vertically stacked fusion semiconductor device comprising:
a semiconductor layer comprising a first buried insulation layer and a second buried insulation layer;
a channel portion that extends in a first direction perpendicular to a top surface of the semiconductor layer, wherein a cross-section of the channel portion has one of a circular shape or polygonal shape, and wherein a part of the channel portion includes a high-concentration ion implantation region adjacent to the semiconductor layer and a storage region for storing charges adjacent to the high concentration ion implantation region;
a common source line extending in a second direction perpendicular to the first direction and wherein the common source line is electrically connected to the channel portion;
a first gate structure disposed over the common source line as viewed from the semiconductor layer and which is electrically connected to the common source line via the channel portion, wherein the first gate structure is a non-volatile memory device comprising a tunneling insulation layer, a charge storage layer, a blocking insulation layer and a first gate electrode layer sequentially stacked on a sidewall of the channel portion;
a second gate structure disposed under the common source line as viewed from the semiconductor layer and which is electrically connected to the common source line via the channel portion, wherein the second gate structure is a dynamic random access memory (DRAM) device comprising a gate insulation layer and a second gate electrode layer sequentially disposed on a sidewall of the channel portion, and wherein at least one of the first gate structure, the common source line, and the second gate structure surround the channel portion;
a plurality of first bit lines disposed on an upper surface of the channel portion and on the first gate structure and which are electrically connected to the first gate structure via the channel portion;
a plurality of second bit lines disposed on the second buried insulation layer of semiconductor layer, wherein the second bit lines are spaced apart from the plurality of first bit lines and disposed on opposite sides of the common source line to the first bit lines, wherein the second bit lines are electrically connected to the second gate structure via the channel portion, and wherein the second bit lines, the second gate structure, the common source line and the first gate structure are sequentially stacked on sidewalls of the channel portion in the first direction starting from the semiconductor layer; and
a plurality of interlayer insulation patterns disposed between the second bit lines, the second gate structure, the common source line, the first gate structure and the first bit lines,
wherein at least one of the first gate structure and the second gate structure extends in the second direction and wherein the second bit lines and the first bit lines extend in a third direction which is perpendicular to the second direction.
